(19) United States
(12) Patent Application Publication
(10) Pub. No.: US 2026/0047481 A1
(43) Pub. Date: Feb. 12, 2026

(54) POWER SEMICONDUCTOR PACKAGE HAVING A PCB AND METHOD FOR FABRICATING A POWER SEMICONDUCTOR PACKAGE

(71) Applicant: Infineon Technologies AG, Neubiberg (DE)

(72) Inventors: Achim Althaus, Regensburg (DE); Andreas Grassmann, Sinzing (DE); Alexander Müller, Pliening (DE); Franz Zollner, Sinzing (DE)

(21) Appl. No.: 19/287,108

(22) Filed: Jul. 31, 2025

(30) Foreign Application Priority Data
Aug. 7, 2024 (DE) 102024207528.0

(51) Int. Cl. H01L 23/055; H01L 21/52; H01L 21/56; H01L 23/10; H01L 23/31; H01L 23/367; H01L 25/065

(52) U.S. Cl. CPC H01L 23/055; H01L 21/52; H01L 21/56; H01L 23/10; H01L 23/3121; H01L 23/3675; H01L 23/3677; H01L 25/0655

(57) ABSTRACT

A power semiconductor package includes: a metal plate having opposing first and second sides; a lateral wall extending along a rim of the first side of the metal plate and surrounding an inner portion of the first side; at least one die carrier arranged over the inner portion of the first side of the metal plate; a power semiconductor die arranged over and electrically coupled to the die carrier, the die carrier electrically isolating the power semiconductor die from the metal plate; and a printed circuit board (PCB) arranged over the lateral wall and covering the inner portion of the first side of the metal plate such that the die carrier and the power semiconductor die are arranged within an interior volume of the power semiconductor package encapsulated by the inner portion of the first side of the metal plate, the lateral wall and the PCB.

### TECHNICAL FIELD

The present disclosure relates to a power semiconductor package, in particular a power semiconductor package comprising a PCB (printed circuit board), as well as to a method for fabricating a power semiconductor package.

### BACKGROUND

A semiconductor package, in particular a power semiconductor package, may comprise one or more semiconductor dies arranged over a die carrier and an encapsulation, e.g. a molded body, encapsulating the semiconductor dies and thereby protecting the semiconductor dies from environmental influences. Such a power semiconductor package may further comprise electrical interconnectors like bond wires, contact clips, etc. for electrical signal and power distribution. These electrical interconnectors are arranged over the semiconductor dies in one or more separate processes prior to fabricating the encapsulation which may add additional costs and/or fabrication time. Furthermore, it may be comparatively complex to adapt such a power semiconductor package for different requirements. Also, such power semiconductor packages may exhibit comparatively large stray inductances. Improved power semiconductor packages as well as improved methods for fabricating a power semiconductor package may help with solving these and other problems.

### SUMMARY

Various aspects pertain to a power semiconductor package, comprising: a metal plate comprising a first side and an opposite second side, a lateral wall extending along a rim of the first side of the metal plate and surrounding an inner portion of the first side of the metal plate, at least one die carrier arranged over the inner portion of the first side of the metal plate, a power semiconductor die arranged over and electrically coupled to the at least one die carrier, wherein the at least one die carrier electrically isolates the power semiconductor die from the metal plate, and a printed circuit board arranged over the lateral wall and covering the inner portion of the first side of the metal plate such that the at least one die carrier and the power semiconductor die are arranged within an interior volume of the power semiconductor package encapsulated by the inner portion of the first side of the metal plate, the lateral wall and the printed circuit board.

Various aspects pertain to a method for fabricating a power semiconductor package, the method comprising: providing a metal plate comprising a first side and an opposite second side, arranging a lateral wall along a rim of the first side of the metal plate such that the lateral wall surrounds an inner portion of the first side of the metal plate, arranging at least one die carrier over the inner portion of the first side of the metal plate, arranging a power semiconductor die over the at least one die carrier and electrically coupling the power semiconductor die to the at least one die carrier, wherein the at least one die carrier electrically isolates the power semiconductor die from the metal plate, and mechanically coupling a printed circuit board to the lateral wall such that the at least one die carrier and the power semiconductor die are arranged within an interior volume of the power semiconductor package encapsulated by the inner portion of the first side of the metal plate, the lateral wall and the printed circuit board.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a sectional view of an exemplary power semiconductor package, wherein a PCB is part of an encapsulation sealing a semiconductor die.

FIG. 2 illustrates a sectional view of a further exemplary power semiconductor package, wherein an interior volume comprising the semiconductor die is at least partially filled with a gel.

FIG. 3 illustrates a sectional view of a further exemplary power semiconductor package, wherein electrical connectors connect the semiconductor die to the PCB.

FIG. 4 illustrates a perspective view of an exemplary metal plate configured to be used in a power semiconductor package like the power semiconductor packages illustrated in FIGS. 1 to 3.

FIG. 5 illustrates a perspective view of a further exemplary metal plate, wherein a plurality of single chip die carriers is arranged on the metal plate.

FIGS. 6A and 6B illustrate a sectional view (FIG. 6A) and a plan view (FIG. 6B) of a power semiconductor die arranged over an exemplary single chip die carrier.

FIG. 7 illustrates a perspective view of the metal plate of FIG. 5, wherein a lateral wall has been arranged on the metal plate, wherein the lateral wall surrounds the semiconductor dies and the die carriers on four sides.

FIG. 8 illustrates a perspective view of a further exemplary power semiconductor package, wherein a PCB has been connected to the lateral wall and the metal plate illustrated in FIG. 7.

FIG. 9 is a flow chart of an exemplary method for fabricating a power semiconductor package.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary”is merely meant as an example, rather than the best or optimal.

The examples of a power semiconductor package described below may use various types of semiconductor dies or circuits incorporated in the semiconductor dies, among them AC/DC or DC/DC converter circuits, power MOS transistors, power Schottky diodes, JFETs (Junction Gate Field Effect Transistors), power bipolar transistors, power integrated circuits, etc.

The power semiconductor die(s) may be manufactured from a specific semiconductor material, for example Si, SiC, SiGe, GaAs, GaN, or from any other semiconductor material, and, furthermore, may contain one or more of inorganic and organic materials that are not semiconductors, such as for example insulators, plastics or metals. The semiconductor dies(s) may have contact pads (or terminals) which may be arranged all at only one main side of the semiconductor die(s) or at both main sides of the semiconductor die(s).

In several examples layers or layer stacks are applied to one another or materials are applied or deposited onto layers. It should be appreciated that any such terms as “applied” or “deposited” are meant to cover literally all kinds and techniques of applying layers onto each other. In particular, they are meant to cover techniques in which layers are applied at once as a whole like, for example, laminating techniques as well as techniques in which layers are deposited in a sequential manner like, for example, sputtering, plating, molding, CVD, etc.

An efficient power semiconductor package and an efficient method for fabricating a power semiconductor package may for example reduce material consumption, ohmic losses, chemical waste, etc. and may thus enable energy and/or resource savings. Improved power semiconductor packages and improved methods for fabricating a power semiconductor package, as specified in this description, may thus at least indirectly contribute to green technology solutions, i.e. climate-friendly solutions providing a mitigation of energy and/or resource use.

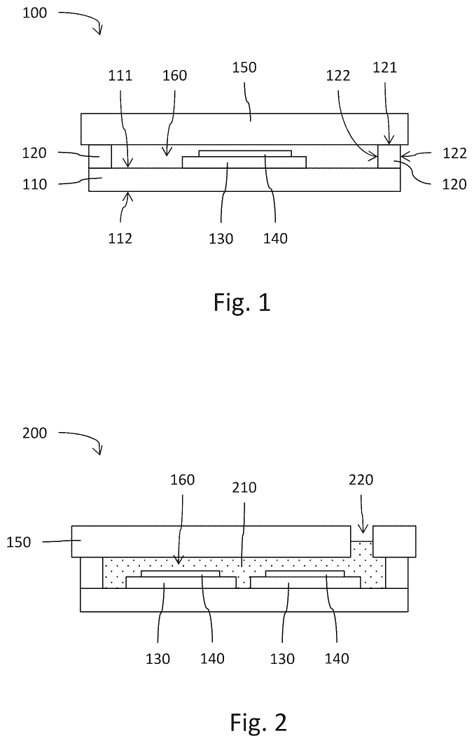

FIG. 1 shows a sectional view of a power semiconductor package 100 comprising a metal plate 110, a lateral wall 120, a die carrier 130, a power semiconductor die 140 and a printed circuit board (PCB) 150. The power semiconductor package 100 may for example be configured to operate with a high voltage, e.g. a voltage of 100V or more, or 500V or more, or 1 kV or more, and/or with a strong electrical current, e.g. a current of 1 A or more, or 10 A or more, or 50 A or more.

The power semiconductor package 100 may comprise any suitable electrical circuit or the power semiconductor package 100 may be configured to be part of any suitable electrical circuit. For example, the power semiconductor package 100 may comprise a half bridge circuit, a full bridge circuit, a converter circuit, an inverter circuit, etc. According to an example, the metal plate 110 may provide sufficient space to house two applications in the power semiconductor package 100, e.g. a traction inverter circuit and an on board charger circuit.

The power semiconductor package 100 may be configured for use in any suitable type of application, for example in automotive applications, industrial applications or household applications. The power semiconductor package 100 may be configured to be connected to a driver circuitry configured to drive the power semiconductor die(s) 140 of the power semiconductor package 100. Such a driver circuitry may for example be arranged on a driver board which may, for example, be arranged above the PCB 150. Alternatively, the driver circuitry may be arranged on the PCB 150 itself. This may, for example, reduce stray inductances in the power semiconductor package 100. Furthermore, gate drivers and/or gate resistors may be placed close to the power semiconductor die(s) 140 which may improve switching behavior.

The metal plate 110 comprises a first side 111 and an opposite second side 112. The first side 111 faces the power semiconductor die 140 and the PCB 150. The metal plate 110 may for example be a baseplate. According to another example, the metal plate 110 is a heatsink and may for example comprise a cooling structure on the second side 112. Such a cooling structure may for example comprise a plurality of pin fins or a plurality of ribbons. In other words, the metal plate 110 may be configured to dissipate heat generated by the power semiconductor die(s) 140 during operation. According to another example, the cooling structure may be absent.

The metal plate 110 may comprise or consist of any suitable metal or metal alloy. According to an example, the metal plate 110 comprises or consists of Al or Cu. The metal plate 110 may have any suitable shape and any suitable dimensions. For example, the metal plate 110 may have an essentially rectangular or quadratic shape as viewed from above the first side 111. The metal plate 110 may for example have edge lengths as viewed from above the first side 111 of 2 cm or more, or 5 cm or more, or 10 cm or more, or 15 cm or more. A thickness of the metal plate, measured between the first and second sides 111, 112 may for example be in the range of about 0.5 mm to about 5 mm. The lower limit of this range may also be about 1 mm or about 1.5 mm and the upper limit may also be about 3 mm or about 2 mm.

The lateral wall 120 extends along a rim of the first side 111 of the metal plate 110 and surrounds an inner portion of the first side 111 of the metal plate 110. The lateral wall 120 may in particular completely surround the inner portion on all four sides.

According to an example, the lateral wall 120 and the metal plate 110 are a monolithic part. In other words, the lateral wall 120 and the metal plate 110 may be fabricated from a single work piece, e.g. a sheet metal. According to another example, the lateral wall 120 and the metal plate 110 are two distinct parts, in particular parts comprising or consisting of different materials or material compositions.

The lateral wall 120 may comprise or consist of any suitable material. For example, the lateral wall 120 may comprise or consist of a metal like Al or Cu or of a metal alloy or of a polymer or a plastic, in particular a thermoplastic. A thermoplastic is a plastic material that becomes malleable when heated up and solidifies when cooled down again.

The lateral wall 120 may have any suitable dimensions. For example, the lateral wall 120 may have a height measured perpendicular to the first side 111 of the metal plate in the range of about 0.5 mm to about 3 mm. The lower limit of this range may also be about 0.8 mm, or about 1 mm, or about 1.2 mm and the upper limit may also be about 2.5 mm, or about 2 mm, or about 1.5 mm. The lateral wall 120 may for example have a width measured parallel to the first side 111 in a similar range as the height. However, the height and the width of the lateral wall 120 need not necessarily be identical.

The lateral wall 120 may have any suitable cross section, for example an essentially rectangular or quadratic cross section (compare FIG. 1). The lateral wall 120 may for example comprise an upper side 121 and lateral sides 122. The upper side 121 may for example be configured to be in direct contact with the PCB 150. According to another example, an adhesive layer, e.g. a solder layer, may be arranged on the upper side 122 and may couple the PCB 150 to the lateral wall 120.

The at least one die carrier 130 is arranged over the inner portion of the first side 111 of the metal plate 110. According to an example, the power semiconductor package 100 comprises a single die carrier 130. According to another example, the power semiconductor package 100 comprises a plurality of die carriers 130, e.g. two, four six, eight, etc. die carriers 130. In the latter case, the die carriers 130 may all be the same type of die carrier and/or have the same dimensions and/or the same shape or the die carriers 130 may be of different types and/or have different dimensions and/or different shapes.

The die carrier 130 may for example be a power electronic substrate. The die carrier 130 may for example comprise an electrically conductive layer and an electrically insulating layer arranged below the electrically conductive layer and configured to insulate the electrically conductive layer from the metal plate 110. The die carrier 130 may for example be a direct copper bond (DCB), a direct aluminum bond (DAB), an active metal braze (AMB), an insulated metal substrate (IMS), a leadframe, or a PCB. The die carrier 130 may for example be soldered or sintered or glued onto the first side 111 of the metal plate 110.

The power semiconductor die 140 is arranged over and electrically coupled to the at least one die carrier 130. According to an example, a single power semiconductor die 140 is arranged over the die carrier 130 or a single power semiconductor die 140 is arranged over each one of a plurality of die carriers 130. According to another example, at least two power semiconductor dies 140 may be arranged over a common die carrier 130. The at least one die carrier 130 is configured to electrically isolate the power semiconductor die(s) 140 from the metal plate 110. The power semiconductor die 140 may for example be soldered or sintered or glued with conductive glue onto the die carrier 130.

The PCB 150 is arranged over the lateral wall 120 and covers the inner portion of the first side 111 of the metal plate 110. This means that the at least one die carrier 130 and the power semiconductor die 140 are arranged within an interior volume 160 of the power semiconductor package 100. The interior volume 160 is encapsulated on all sides by the inner portion of the first side 111 of the metal plate 110, the lateral wall 120 and the PCB 150. This may in particular mean that the power semiconductor die 140 is sealed within the interior volume 160, wherein the PCB 150 is used as a lid that seals the top of the interior volume by being coupled to the lateral wall 120. In this manner, the power semiconductor die 140 may be protected from environmental influences using the metal plate 110, the lateral wall 120 and the PCB 150 as a seal comparable to a molded body.

FIG. 2 shows a sectional view of a further power semiconductor package 200 which may be similar or identical to the power semiconductor package 100, except for the differences described in the following.

The power semiconductor package 200 comprises all components described with respect to the power semiconductor package 100 and the power semiconductor package 200 additionally comprises a gel (or a mold compound without filler particles) 210 arranged within the interior volume 160 of the power semiconductor package 200. In FIG. 2, the gel 210 is shown to completely fill the interior volume 160. However, according to another example, the gel 210 only partially fills the interior volume 160. For example, only a lower portion of the interior volume 160 is filled by the gel 210 and an upper portion of the interior volume 160 is free of the gel 210. Additionally or alternatively, the interior volume 160 may comprise one or more voids which are not filled by the gel 210.

In any case, the gel 210 may be configured to electrically isolate terminals of the power semiconductor die 130, for example gate, drain and source terminals, from each other and/or to electrically isolate a plurality of power semiconductor dies 130 from each other. To this effect, the gel 210 may comprise or consist of any suitable dielectric material.

According to an exemplary method for fabricating the semiconductor package 200, the gel 210 is filled into the interior volume 160 after the PCB 150 has been connected to the lateral wall 120. For this reason, the PCB 150 may comprise one or more holes 220 configured for filling the gel 210 into the interior volume 160. For example, one or more first holes 220 may be configured as inlets for the gel 210 and one or more second holes 220 may be configured as outlets for gas being displaced from the interior volume 160. As shown in FIG. 2, the gel 210 may at least partially or even completely fill the hole(s) 220.

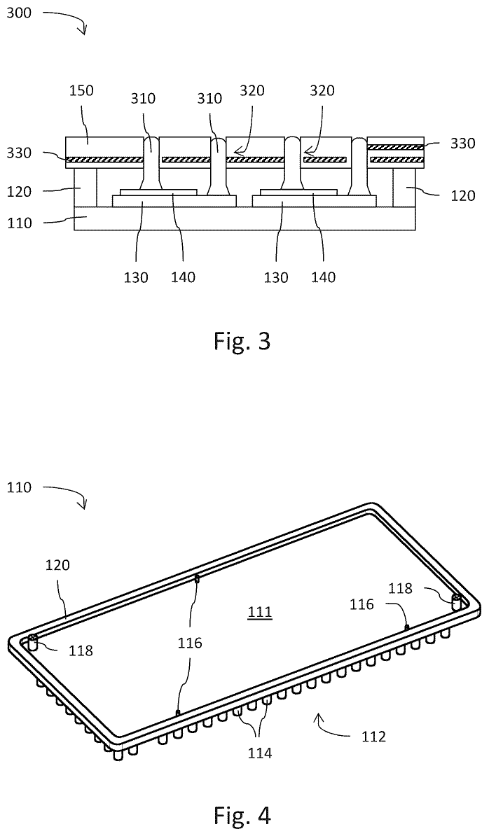

FIG. 3 shows a sectional view of a further power semiconductor package 300 which may be similar or identical to the power semiconductor package 100 or 200, except for the differences described in the following.

In particular, the power semiconductor package 300 comprises electrical connectors 310 which electrically connect the power semiconductor dies 140 to the PCB 150. The electrical connectors 310 may in particular connect power terminals of the power semiconductor dies 140, e.g. source, drain, emitter or collector terminals, to the PCB 150. The power semiconductor package may of course also comprise the gel 210 (not shown in FIG. 3).

As shown in FIG. 3, the electrical connectors 310 may be arranged on an upper side of the die carrier(s) 130 and/or on an upper side of the power semiconductor dies 140. The electrical connectors 310 may for example be soldered to the die carrier(s) 130 and/or to the power semiconductor dies 140.

The electrical connectors 310 may partially or completely extend through through-holes 320 in the PCB 150. The through-holes 320 may be different from the one or more holes 220 (compare FIG. 2) and may specifically be configured to accept the electrical connectors 310. Furthermore, the electrical connectors 310 may be electrically connected to one or more conductive tracks 330 of the PCB 150, for example via the through-holes 320. The through-holes 320 may have any suitable diameter, for example a diameter of about 1 mm, or about 1.5 mm, or about 2 mm.

The PCB 150 may provide a redistribution structure of the semiconductor package 300. For example, individual power semiconductor dies 140 may be electrically connected to each other via the electrical connectors 310 and the conductive tracks 330 of the PCB 150. In other words, no lateral connectors like contact clips between individual power semiconductor dies 140 need to be present in the interior volume 160 because the PCB 150 may fulfill this role. The PCB 150 may in particular be a redistribution structure for both power connections and signal connections.

The electrical connectors 310 may comprise or consist of any suitable metal or metal alloy. According to an example, the electrical connectors 310 consist of solder material. Fabricating the electrical connectors 310 may for example comprise a process of depositing a solder paste or a solder preform (e.g. preform wires) on the power semiconductor dies 140 and/or on the die carrier(s) 130 via the through-holes 320 and then soldering the solder paste or the solder preform.

According to an example, the PCB 150 comprises external power terminals of the power semiconductor package 300 (not shown in FIG. 3). The external power terminals may be connected to the power semiconductor dies 140 via the conductive tracks 330 and the electrical connectors 310. The external power terminals may, for example, comprise a terminal for a positive supply voltage, a terminal for a negative supply voltage and a phase current terminal.

FIG. 4 shows a perspective view of the metal plate 110 according to a specific example. In the example shown in FIG. 4, the lateral wall 120 and the metal plate 110 are a monolithic part. Fabricating the lateral wall 120 may for example comprise a punching process. Alternatively, a metal frame structure may be arranged over and coupled to the first side 111 of the metal plate 110 in order to provide the lateral wall 120, wherein the coupling process for example comprises welding.

According to the example shown in FIG. 4, the second side 112 of the metal plate 110 comprises a cooling structure 114. The cooling structure 114 may in particular comprise a plurality of pin fins or a plurality of ribbons. The second side 112 (and therefore also the cooling structure 114) may be configured to be in direct contact with a cooling fluid like water or air.

The metal plate 110 may further comprise spacers 116 arranged on the first side 111 and configured to set a distance between the first side 111 and the PCB 150. To this effect, the spacers 116 may (slightly) extend vertically beyond the height of the lateral wall 120 such that a solder layer or a layer comprising glue can be arranged between the PCB 150 and the upper side 121 of the lateral wall 120. The spacers 116 may be used because it may be easier to set a desired height of the spacers with the required accuracy (e.g. ±15 μm) than to set the desired height with the required accuracy along the whole length of the lateral wall 120.

The metal plate 110 may further comprise positioning pins 118 configured to be inserted into corresponding positioning holes of the PCB 150 in order to ensure that the PCB 150 is arranged over the metal plate 110 in the correct position. The metal plate 110 and the spacers 116 and/or the positioning pins 118 may for example be a monolithic part.

In the case that the lateral wall 120 comprises or consists of a metal or a metal alloy, the PCB 150 may for example be soldered onto the lateral wall 120. To this end, a solder preform may be deposited on the upper side 121 of the lateral wall 120.

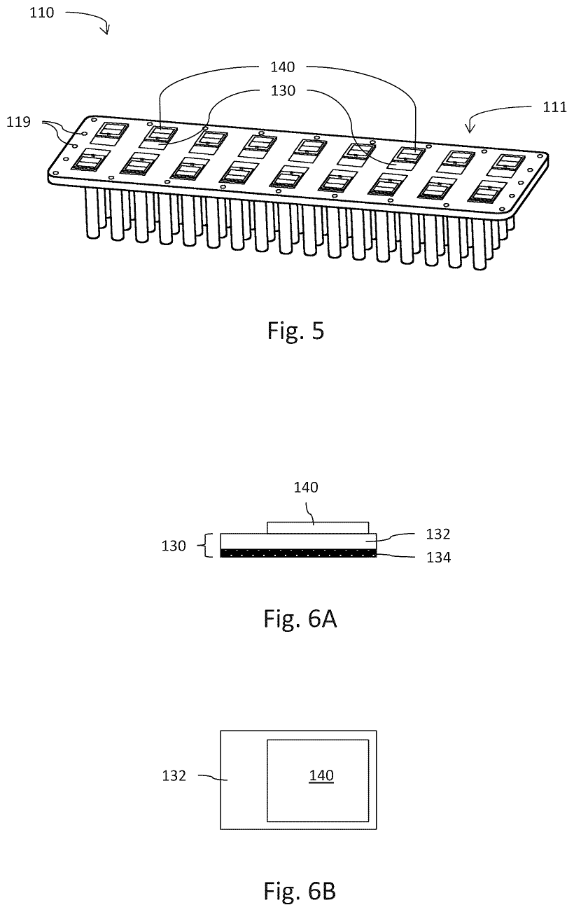

FIG. 5 shows a perspective view of the metal plate 110 according to a further specific example. The metal plate 110 according to the example of FIG. 5 may be similar or identical to the metal plate 110 according to the example shown in FIG. 4, except for the differences described in the following.

In particular, in the example of FIG. 5 the metal plate 110 and the lateral wall 120 are not a monolithic part. This may for example mean that the lateral wall 120 comprises or consists of a different material than the metal plate 110, e.g. a thermoplastic material, and that the lateral wall 120 is configured to be attached to the metal plate, using for example a heat staking process and/or glue.

As shown in FIG. 5, a rim of the first side 111 of the metal plate 110 may comprise a plurality of connection holes 119 which may be configured to accept pins of the lateral wall 120. In this manner, a mechanical coupling between the metal plate 110 and the lateral wall 120 may be improved.

The rim of the first side 111 of the metal plate 110 surrounds an inner portion of the first side 111, wherein the inner portion is configured to accept at least one die carrier 130. As shown in the example of FIG. 5, a plurality of die carriers 130 may be arranged over the inner portion of the first side 111.

The example of FIG. 5 in particular shows that each of the power semiconductor dies 140 is arranged over an individual die carrier 130. The die carriers 130 may for example be arranged over the first side 111 of the metal plate 110 using a pick-and-place process. The die carriers 130 may be arranged over the first side 111 in any suitable pattern, for example in one or more rows or in a matrix. The die carriers 130 may also for example be arranged in a so called “super-symmetrical” pattern which provides an optimized switching behavior of the power semiconductor dies 140. The die carriers 130 may be arranged at a minimum distance from one another, in particular a minimum distance which ensures proper electrical insulation between adjacent ones of the die carriers 130.

FIG. 6A shows a sectional view and FIG. 6B shows a plan view of the die carrier 130 and the power semiconductor die 140, according to a specific example. The die carrier 130 of the example of FIGS. 6A and 6B is configured to carry a single power semiconductor die 140. For this reason, a circumference of the die carrier 130 may extend only slightly beyond a circumference of the power semiconductor die 140 (e.g. no more than 2 mm or no more than 1 mm) or the circumference of the die carrier 130 may essentially be flush with the circumference of the power semiconductor die 140, as viewed from above the power semiconductor die 140. However, the circumference of the die carrier 130 may significantly extend beyond the circumference of the power semiconductor die 140 at a single edge of the power semiconductor die 140 (e.g. more than 3 mm) in order to provide space for an electrical connector 310 on the upper side of the die carrier 130 and laterally next to the power semiconductor die 140 (this case is shown in FIGS. 6A and 6B).

The die carrier 130 may, for example, comprise a metal layer or metal piece 132 arranged on an electrically insulating layer 134, wherein the insulating layer 134 is configured to insulate the metal layer or piece 132 from the metal plate 110. The insulating layer 134 may for example be a ceramic layer or a polymer layer, in particular a polymer foil. According to an example, the die carrier 130 may comprise a further metal layer arranged below the insulating layer 134.

In the case that the insulating layer 134 is a polymer layer, the insulating layer may have adhesive properties and may be configured to attach the die carrier 130 to the metal plate 110. In the case that the insulating layer 134 is a ceramic layer, an additional adhesive layer, e.g. a layer comprising solder material, sinter material or glue, may be used to attach the die carrier 130 to the metal plate 110.

Since each die carrier 130 may be configured to carry a single power semiconductor die 140, the size of each die carrier 130 may be minimized, as outlined above. This may reduce the costs of the power semiconductor packages 100 to 300, since the die carriers 130 may contribute to a significant part of the overall costs of the semiconductor package. Furthermore, it may be possible to use different types of die carriers 130 and/or die carriers 130 with different shapes and/or different sizes for different individual power semiconductor dies 140 of the power semiconductor packages 100 to 300. This may also reduce the costs of the semiconductor package and/or improve the electrical and/or thermal properties of the semiconductor package. Furthermore, this may make the power semiconductor packages 100 to 300 more easily adaptable to different requirements or applications.

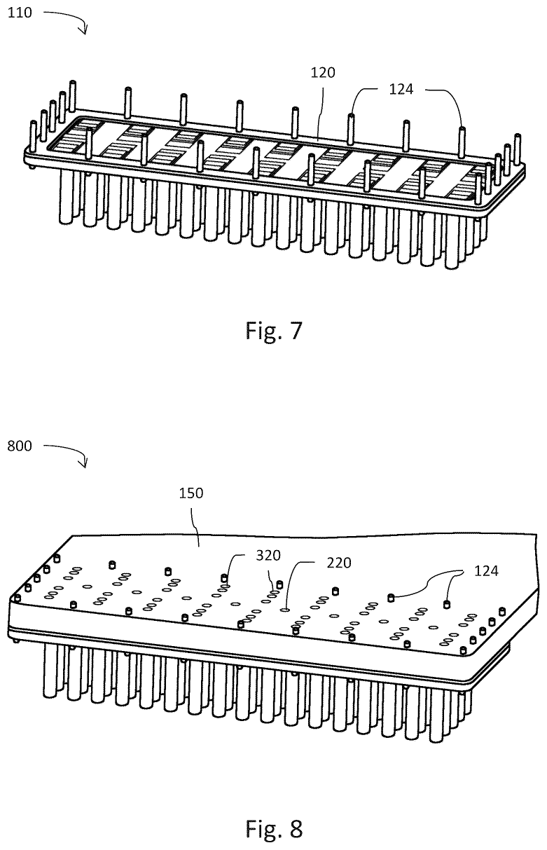

FIG. 7 shows the metal plate 110 according to the example of FIG. 6 after the lateral wall 120 has been attached to the metal plate 110. The lateral wall 120 may, for example, comprise or consist of a thermoplastic material and the lateral wall 120 may be attached to the metal plate 110 using a heat staking connection.

As shown in FIG. 7, the lateral wall 120 may comprise a plurality of pins 124 configured to be inserted into corresponding holes of the PCB 150. This may improve the mechanical bond between the lateral wall 120 and the PCB 150.

FIG. 8 shows a perspective view of a power semiconductor package 800 which may be similar or identical to the power semiconductor packages 100 to 300. FIG. 8 in particular shows the power semiconductor package 800 after the PCB 150 has been arranged over the metal plate 110 and the lateral wall 120 shown in FIG. 7. The PCB 150 may be coupled to the lateral wall 120 with a heat staking connection and/or glue. As shown in FIG. 8, pins 124 of the lateral wall 120 may extend through corresponding holes in the PCB 150 in order to improve a mechanical strength of the heat staking connection. In the case that the lateral wall 120 and the metal plate are a monolithic part, the PCB 150 may instead be soldered to the lateral wall 120.

Note that in FIG. 8 the PCB 150 is larger than the metal plate 110 as viewed from above the PCB 150. The reason for this may be for example that the PCB 150 comprises external power terminals of the semiconductor package 800 configured to connect the power semiconductor package 800 to an external appliance and the PCB 150 therefore needs to be large enough to accommodate these external power terminals.

As shown in FIG. 8, the PCB 150 of the power semiconductor package 800 may for example comprise the holes 220 for filling the gel 210 into the interior volume 160 of the semiconductor package 800 (compare FIG. 2). The PCB 150 may comprise the through-holes 320 configured to accept the electrical connectors 310 (compare FIG. 3).

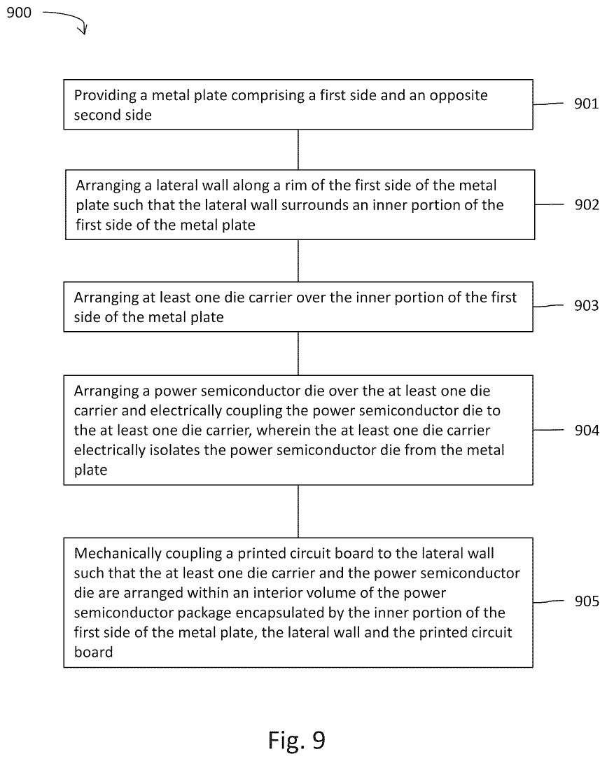

FIG. 9 is a flow chart of an exemplary method 900 for fabricating a power semiconductor package. The method 900 may for example be used to fabricate the power semiconductor packages 100 to 800.

The method 900 comprises at 901 a process of providing a metal plate comprising a first side and an opposite second side; at 902 a process of arranging a lateral wall along a rim of the first side of the metal plate such that the lateral wall surrounds an inner portion of the first side of the metal plate; at 903 a process of arranging at least one die carrier over the inner portion of the first side of the metal plate; at 904 a process of arranging a power semiconductor die over the at least one die carrier and electrically coupling the power semiconductor die to the at least one die carrier, wherein the at least one die carrier electrically isolates the power semiconductor die from the metal plate; and at 905 a process of mechanically coupling a printed circuit board to the lateral wall such that the at least one die carrier and the power semiconductor die are arranged within an interior volume of the power semiconductor package encapsulated by the inner portion of the first side of the metal plate, the lateral wall and the printed circuit board.

The process 902 of arranging the lateral wall along the rim of the first side of the metal plate may for example comprise providing the metal plate and the lateral wall as a monolithic part. According to another example, the lateral wall may be attached to the metal plate, e.g. using a heat staking process.

The method 900 may for example comprise a further process of inserting a solder preform into through-holes in the printed circuit board and soldering the solder preform in order to fabricate electrical connectors electrically connecting power terminals of the power semiconductor dies to conductive tracks of the printed circuit board.

In the following, the power semiconductor package and the method for fabricating a power semiconductor package are further explained using specific examples.

Example 1 is a power semiconductor package, comprising: a metal plate comprising a first side and an opposite second side, a lateral wall extending along a rim of the first side of the metal plate and surrounding an inner portion of the first side of the metal plate, at least one die carrier arranged over the inner portion of the first side of the metal plate, a power semiconductor die arranged over and electrically coupled to the at least one die carrier, wherein the at least one die carrier electrically isolates the power semiconductor die from the metal plate, and a printed circuit board arranged over the lateral wall and covering the inner portion of the first side of the metal plate such that the at least one die carrier and the power semiconductor die are arranged within an interior volume of the power semiconductor package encapsulated by the inner portion of the first side of the metal plate, the lateral wall and the printed circuit board.

Example 2 is the power semiconductor package of example 1, wherein the lateral wall is a monolithic part of the metal plate.

Example 3 is the power semiconductor package of example 2, wherein the printed circuit board is soldered to the lateral wall.

Example 4 is the power semiconductor package of example 1, wherein the lateral wall is a plastic frame.

Example 5 is the power semiconductor package of example 4, wherein the printed circuit board is mechanically coupled to the plastic frame by a heat staking connection.

Example 6 is the power semiconductor package of one of the preceding examples, wherein the interior volume is at least partially filled with a gel.

Example 7 is the power semiconductor package of one of the preceding examples, further comprising: electrical connectors extending through through-holes in the printed circuit board and electrically connecting power terminals of the power semiconductor die to conductive tracks of the printed circuit board.

Example 8 is the power semiconductor package of example 7, wherein the electrical connectors consist of solder material.

Example 9 is the power semiconductor package of one of the preceding examples, wherein the printed circuit board comprises external power terminals of the power semiconductor package.

Example 10 is the power semiconductor package of one of the preceding examples, wherein the power semiconductor package comprises a plurality of die carriers and a plurality of semiconductor dies, and wherein each of the power semiconductor dies is arranged over an individual die carrier.

Example 11 is the power semiconductor package of example 10, wherein each die carrier comprises a metal piece or metal layer and an electrically insulating layer arranged between the metal piece or metal layer and the metal plate.

Example 12 is the power semiconductor package of example 11, wherein the insulating layer is a ceramic layer.

Example 13 is the power semiconductor package of example 11, wherein the insulating layer is a polymer layer.

Example 14 is the power semiconductor package of one of examples 10 to 13, wherein the plurality of die carriers comprises at least two different types of die carriers, and wherein the different types of die carriers have different dimensions and/or different shapes, and/or wherein different types of power semiconductor dies are arranged over the different types of die carriers.

Example 15 is the power semiconductor package of one of the preceding examples, wherein the second side of the metal plate comprises a cooling structure, in particular wherein the second side of the metal plate comprises a plurality of pin fins or a plurality of ribbons.

Example 16 is the power semiconductor package of one of the preceding examples, wherein each power semiconductor die comprises gate terminals and source terminals arranged on a first side of the power semiconductor die, and wherein the first side of each power semiconductor die faces the printed circuit board.

Example 17 is a method for fabricating a power semiconductor package, the method comprising: providing a metal plate comprising a first side and an opposite second side, arranging a lateral wall along a rim of the first side of the metal plate such that the lateral wall surrounds an inner portion of the first side of the metal plate, arranging at least one die carrier over the inner portion of the first side of the metal plate, arranging a power semiconductor die over the at least one die carrier and electrically coupling the power semiconductor die to the at least one die carrier, wherein the at least one die carrier electrically isolates the power semiconductor die from the metal plate, and mechanically coupling a printed circuit board to the lateral wall such that the at least one die carrier and the power semiconductor die are arranged within an interior volume of the power semiconductor package encapsulated by the inner portion of the first side of the metal plate, the lateral wall and the printed circuit board.

Example 18 is the method of example 17, further comprising: filling the interior volume at least partially with a gel, wherein the gel is filled into the interior volume through one or more holes in the printed circuit board.

Example 19 is the method of example 17 or 18 further comprising: inserting a solder preform into through-holes in the printed circuit board, and soldering the solder preform to fabricate electrical connectors electrically connecting power terminals of the power semiconductor dies to conductive tracks of the printed circuit board.

Example 20 is the method of one of examples 17 to 19, wherein mechanically coupling the printed circuit board to the lateral wall comprises soldering or heat staking the printed circuit board to the lateral wall.

Example 21 is an apparatus comprising means for performing the method according to anyone of examples 17 to 20.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A power semiconductor package, comprising:
a metal plate comprising a first side and an opposite second side;
a lateral wall extending along a rim of the first side of the metal plate and surrounding an inner portion of the first side of the metal plate;
at least one die carrier arranged over the inner portion of the first side of the metal plate;
a power semiconductor die arranged over and electrically coupled to the at least one die carrier, wherein the at least one die carrier electrically isolates the power semiconductor die from the metal plate; and
a printed circuit board arranged over the lateral wall and covering the inner portion of the first side of the metal plate such that the at least one die carrier and the power semiconductor die are arranged within an interior volume of the power semiconductor package encapsulated by the inner portion of the first side of the metal plate, the lateral wall and the printed circuit board.

2. The power semiconductor package of claim 1, wherein the lateral wall is a monolithic part of the metal plate.

3. The power semiconductor package of claim 2, wherein the printed circuit board is soldered to the lateral wall.

4. The power semiconductor package of claim 1, wherein the lateral wall is a plastic frame.

5. The power semiconductor package of claim 4, wherein the printed circuit board is mechanically coupled to the plastic frame by a heat staking connection.

6. The power semiconductor package of claim 1, wherein the interior volume is at least partially filled with a gel.

7. The power semiconductor package of claim 1, further comprising:
a plurality of electrical connectors extending through a plurality of through-holes in the printed circuit board and electrically connecting a plurality of power terminals of the power semiconductor die to a plurality of conductive tracks of the printed circuit board.

8. The power semiconductor package of claim 7, wherein the electrical connectors consist of solder material.

9. The power semiconductor package of claim 1, wherein the printed circuit board comprises a plurality of external power terminals of the power semiconductor package.

10. The power semiconductor package of claim 1, wherein the power semiconductor package comprises a plurality of die carriers and a plurality of semiconductor dies, and wherein each of the power semiconductor dies is arranged over an individual die carrier.

11. The power semiconductor package of claim 10, wherein each die carrier comprises a metal piece or metal layer and an electrically insulating layer arranged between the metal piece or metal layer and the metal plate.

12. The power semiconductor package of claim 11, wherein the insulating layer is a ceramic layer.

13. The power semiconductor package of claim 11, wherein the insulating layer is a polymer layer.

14. The power semiconductor package of claim 10, wherein the plurality of die carriers comprises at least two different types of die carriers, and wherein the different types of die carriers have different dimensions and/or different shapes, and/or wherein different types of power semiconductor dies are arranged over the different types of die carriers.

15. The power semiconductor package of claim 1, wherein the second side of the metal plate comprises a plurality of pin fins or a plurality of ribbons.

16. The power semiconductor package of claim 1, wherein each power semiconductor die comprises a plurality of gate terminals and a plurality of source terminals arranged on a first side of the power semiconductor die, and wherein the first side of each power semiconductor die faces the printed circuit board.

17. A method for fabricating a power semiconductor package, the method comprising:
providing a metal plate comprising a first side and an opposite second side;
arranging a lateral wall along a rim of the first side of the metal plate such that the lateral wall surrounds an inner portion of the first side of the metal plate;
arranging at least one die carrier over the inner portion of the first side of the metal plate;
arranging a power semiconductor die over the at least one die carrier and electrically coupling the power semiconductor die to the at least one die carrier, wherein the at least one die carrier electrically isolates the power semiconductor die from the metal plate; and
mechanically coupling a printed circuit board to the lateral wall such that the at least one die carrier and the power semiconductor die are arranged within an interior volume of the power semiconductor package encapsulated by the inner portion of the first side of the metal plate, the lateral wall and the printed circuit board.

18. The method of claim 17, further comprising:
filling the interior volume at least partially with a gel,
wherein the gel is filled into the interior volume through one or more holes in the printed circuit board.

19. The method of claim 17, further comprising:
inserting a solder preform into a plurality of through-holes in the printed circuit board; and
soldering the solder preform to fabricate a plurality of electrical connectors electrically connecting a plurality of power terminals of the power semiconductor dies to a plurality of conductive tracks of the printed circuit board.

20. The method of claim 17, wherein mechanically coupling the printed circuit board to the lateral wall comprises soldering or heat staking the printed circuit board to the lateral wall.
